(19) United States
(12) Patent Application Publication
(10) Pub. No.: US 2025/0119985 A1
(43) Pub. Date: Apr. 10, 2025

(54) HEATING PLATE AND METHOD OF MANUFACTURING HEATING PLATE

(71) Applicant: SEMES CO., LTD., Cheonan-si (KR)

(72) Inventors: Ju Mi LEE, Seoul (KR); Jae Oh BANG, Seoul (KR); Min Young KIM, Hwaseong-si (KR)

(73) Assignee: SEMES CO., LTD., Cheonan-si (KR)

(21) Appl. No.: 18/897,107

(22) Filed: Sep. 26, 2024

(30) Foreign Application Priority Data
Oct. 4, 2023 (KR) 10-2023-0131876

(51) Int. Cl. H05B 3/28; H05B 3/12

(52) U.S. Cl. CPC H05B 3/283; H05B 3/12; H05B 2203/017

(57) ABSTRACT

Disclosed is a heating plate for supporting and heating a substrate, the heating plate including: a base layer on which a substrate is seated; a heating wire layer located under the base layer and including a transition metal material and a metal bond; and a protective layer located under the heating wire layer and including a ceramic material and an additive material, in which the additive material is melted at a lower temperature than the ceramic material and the transition metal material, and the metal bond is a material produced by bonding of components contained in the transition metal material and the additive material.

### CROSS-REFERENCE TO RELATED APPLICATIONS

This application claims priority to and the benefit of Korean Patent Application No. 10-2023-0131876 filed in the Korean Intellectual Property Office on Oct. 4, 2023, the entire contents of which are incorporated herein by reference.

### TECHNICAL FIELD

The present invention relates to a heating plate for treating a substrate and a method of manufacturing a heating plate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

Here, the heat treatment process is carried out by transferring a substrate to a heat treating chamber and heating the transferred substrate. In this case, the substrate is mounted on a heating plate and is heat treated by receiving heat from the heated heating plate in the related art.

Traditional heating plates for heating a substrate are formed to heat the entire substrate uniformly, and in order to heat the entire area of the substrate uniformly, the resistance of the heating wires mounted on the heating plate needs be adjusted so that each heating wire is heated to a uniform temperature.

On the other hand, there are traditional methods of removing a portion of the volume by emitting a laser to heating wires that is not uniformly formed in line width or thickness, but this method is difficult to be applied uniformly to the entire heating wire, so it is difficult to control the resistance of the heating wire finely.

### SUMMARY OF THE INVENTION

The present invention has been made in an effort to provide a heating plate that is capable of adjusting easily the resistance of a heating wire for heat treating a substrate, and a method of manufacturing the heating plate.

The object of the present invention is not limited thereto, and other objects not mentioned will be clearly understood by those of ordinary skill in the art from the following description.

An exemplary embodiment of the present invention provides a heating plate for supporting and heating a substrate, the heating plate including: a base layer on which a substrate is seated; a heating wire layer located under the base layer and including a transition metal material and a metal bond; and a protective layer located under the heating wire layer and including a ceramic material and an additive material, in which the additive material is melted at a lower temperature than the ceramic material and the transition metal material, and the metal bond is a material produced by bonding of components contained in the transition metal material and the additive material.

According to the exemplary embodiment, the heating wire layer may include: an upper layer including the transition metal material; and a lower layer including the transition metal material and the metal bond, and the upper layer may not be provided with the metal bond.

According to the exemplary embodiment, the additive material may have a melting point lower than a melting point of the transition metal material.

According to the exemplary embodiment, the heating wire layer may include a precious metal, a platinum group metal, or an alloy of the precious metal and the platinum group metal.

According to the exemplary embodiment, the heating wire layer may further include a ceramic material and a heat dissipating material.

According to the exemplary embodiment, the heat dissipating material may be aluminum oxide.

According to the exemplary embodiment, the protective layer includes silicon dioxide as the ceramic material and includes any one of PbO, V₂O₂, and TeO₂ as the additive material.

According to the exemplary embodiment, the protective layer may further include a heat dissipating material.

According to the exemplary embodiment, the heat dissipating material may be aluminum oxide.

According to the exemplary embodiment, the heating wire layer may be supplied with power to be heated, and the heat generated in the heating wire layer may be conducted through the base layer to the substrate.

Another exemplary embodiment of the present invention provides a method of manufacturing a heating plate heat treating a substrate, the method including: a base preparation operation of preparing a base layer; a heating wire layer formation operation of forming a heating wire layer including a transition metal material on the base layer; a protective layer formation operation of forming a protective layer including a ceramic material and an additive material to cover the heating wire layer; and a resistance adjustment operation of adjusting a resistance of the heating wire layer, in which in the resistance adjustment operation, the heating wire layer is heated to a temperature or above at which the additive material melts in the protective layer, the melted additive material is bonded with the transition metal material in the heating wire layer to form a metal bond, to adjust the resistance of the heating wire layer.

According to the exemplary embodiment, in the resistance adjustment operation, a laser may be emitted to penetrate the ceramic material of the protective layer to heat the heating wire layer.

According to the exemplary embodiment, the metal bond may be formed at an interface where the heating wire layer and the protective layer are adjacent.

According to the exemplary embodiment, the additive material may have a melting point lower than a melting point of the transition metal material.

According to the exemplary embodiment, the heating wire layer may include a precious metal, a platinum group metal, or an alloy of the precious metal and the platinum group metal.

According to the exemplary embodiment, the heating wire layer may further include a ceramic material and a heat dissipating material.

According to the exemplary embodiment, the protective layer includes silicon dioxide as the ceramic material and includes any one of PbO, V₂O₂, and TeO₂ as the additive material.

According to the exemplary embodiment, the heating wire layer formation operation may include: a heating wire layer printing operation of printing the heating wire layer based on the base layer; and a heat treatment operation of heat treating the printed heating wire layer.

According to the exemplary embodiment, the method may further include an insulating layer formation operation of forming an insulating layer between the base layer and the heating wire layer, wherein the insulating layer formation operation is performed between the base preparation operation and the heating wire layer formation operation, and is performed when the base layer includes a conductive material.

Still another exemplary embodiment of the present invention provides a method of manufacturing a heating plate heat treating a substrate, the method including: a base preparation operation of preparing a base layer; an insulating layer formation operation of forming an insulating layer on the base layer; a heating wire layer formation operation of forming a heating wire layer including a transition metal material, a ceramic material, and a heat dissipating material on the insulating layer, wherein the heating wire layer is printed on the insulating layer, the printed heating wire layer is heat treated, and the heating wire layer includes a precious metal, a platinum group metal, or an alloy of the precious metal and the platinum group metal; a protective layer formation operation of forming a protective layer including a ceramic material and an additive material to cover the heating wire layer, wherein the additive material has a melting point lower than a melting point of the transition metal material, the protective layer uses silicon dioxide as the ceramic material, and uses any one of PbO, V₂O₂, and TeO₂ as the additive material; and a resistance adjustment operation of adjusting a resistance of the heating wire layer, in which in the resistance adjustment operation, a laser penetrates the ceramic material of the protective layer to heat the heating wire layer to a temperature or above at which the additive material melts in the protective layer, and the melted additive material is bonded with the transition metal material of the heating wire layer to form a metal bond on an interface where the heating wire layer and the protective layer are adjacent, to adjust the resistance of the heating wire layer.

The present invention has the effect of facilitating the adjustment of the resistance of a heat wire for heat treating a substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a top plan view schematically illustrating one example of a heat treating chamber of FIG. 3 or FIG. 4.

FIG. 7 is a front view of the heat treating chamber of FIG. 6.

FIG. 8 is a cross-sectional view schematically illustrating one example of the liquid treating chamber of FIG. 3 or FIG. 4.

FIG. 9 is a partial cross-sectional view of a heating plate illustrated in FIG. 7 through a longitudinal incision.

FIG. 10 is a flowchart of a method of manufacturing a heating plate according to an exemplary embodiment of the present invention.

FIGS. 11 to 13 are partial cross-sectional views of the heating plate according to the sequence of the method of manufacturing the heating plate illustrated in FIG. 10.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

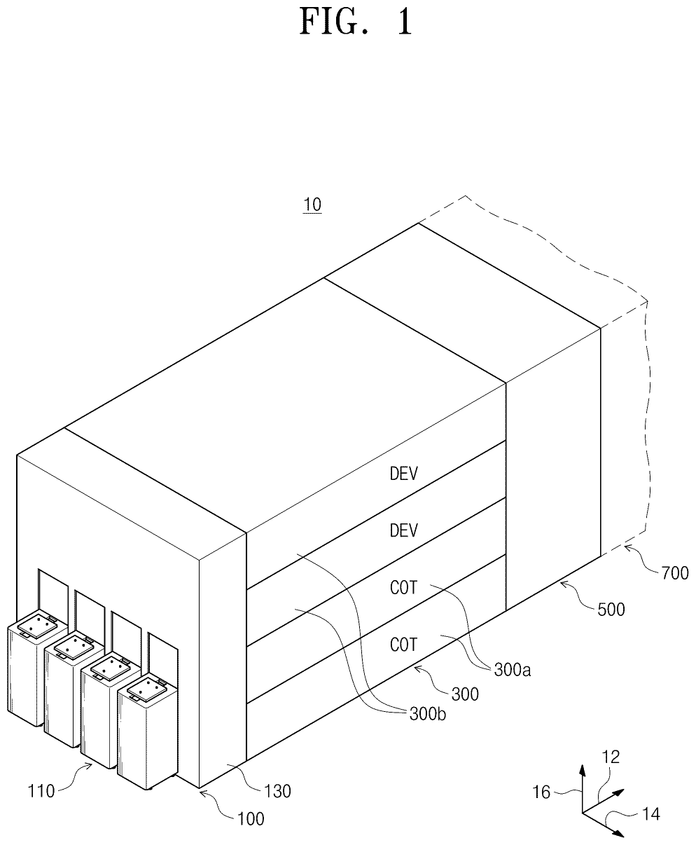

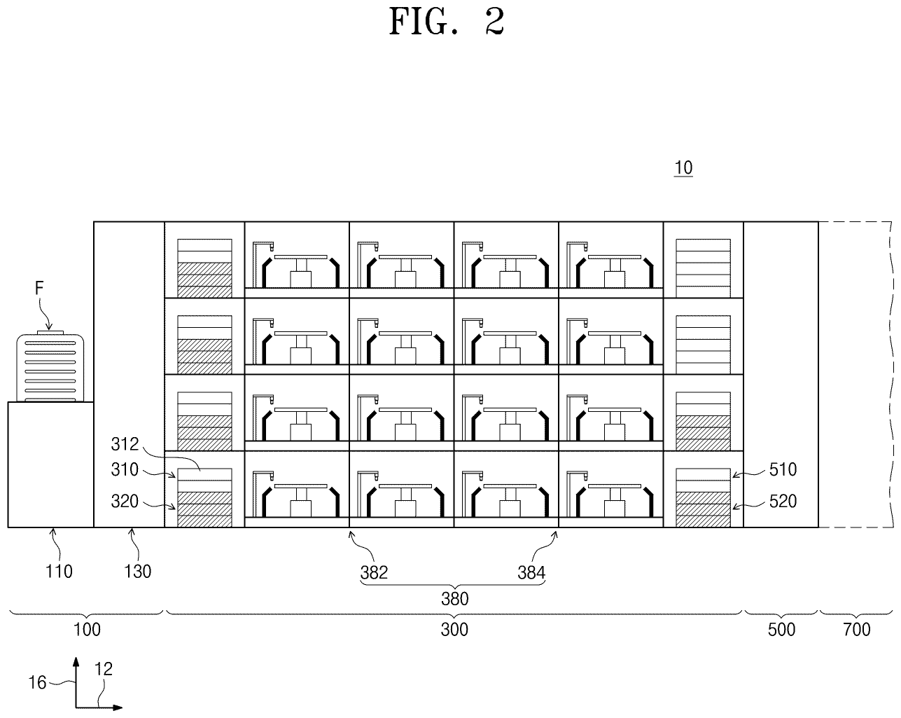

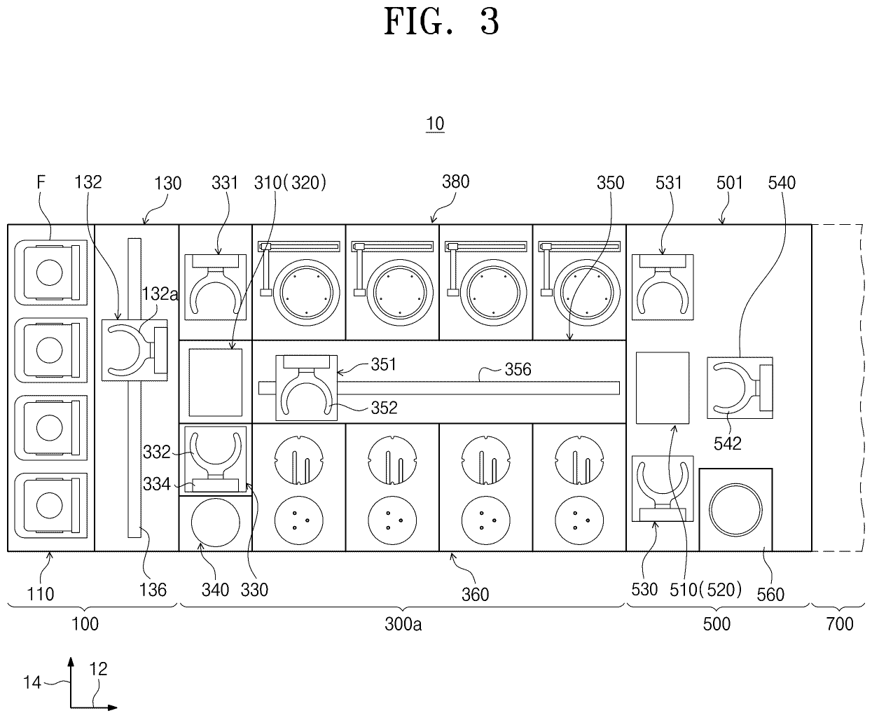

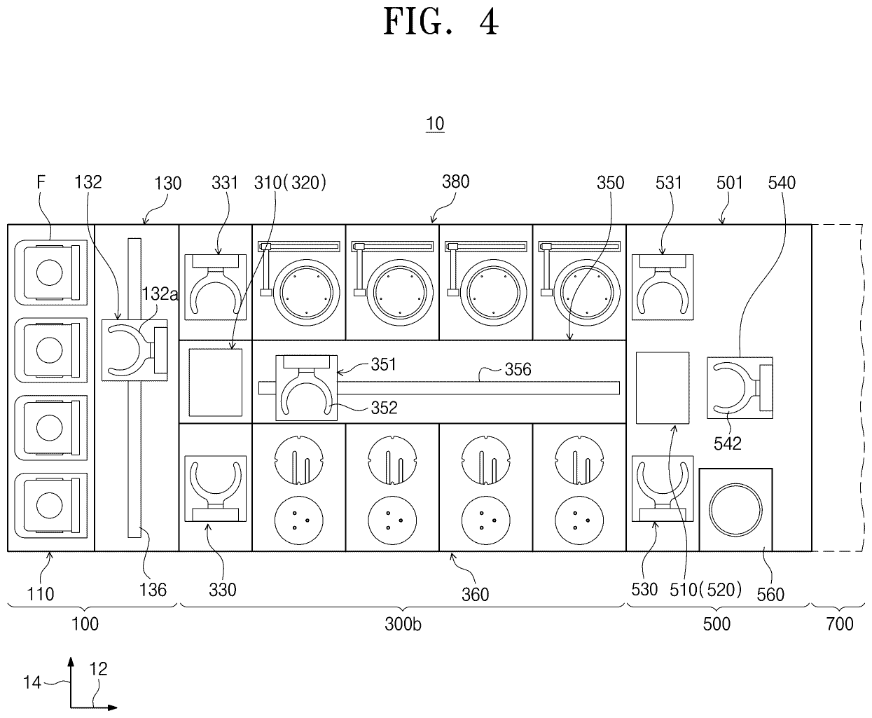

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be located below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index module 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided with respect to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 360 may be stacked along the third direction 16.

In one example, the liquid treating chambers 380 include a front end liquid treating chamber 380a and a rear end liquid treating chamber 380b. The front end liquid treating chamber 380a is disposed relatively close to the index module 100, and the rear end liquid treating chamber 380b is disposed further close to the interface module 500.

The front end liquid treating chamber 380a applies a first liquid to the substrate W, and the rear end liquid treating chamber 380b applies a second liquid to the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the applying block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber 380 performs the development process by supplying a developer onto the substrate W and developing the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

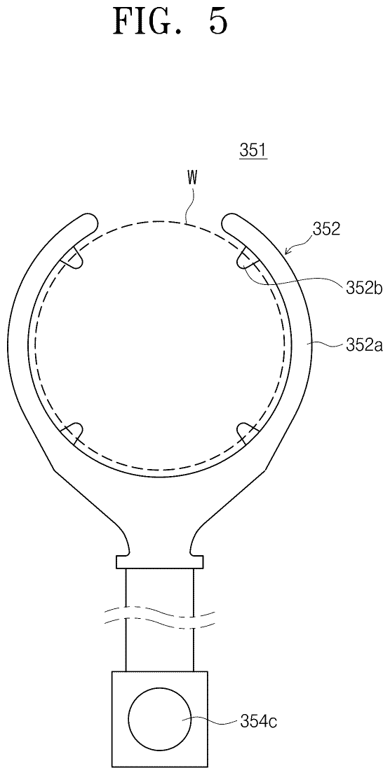

FIG. 5 is a diagram illustrating one example of a hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

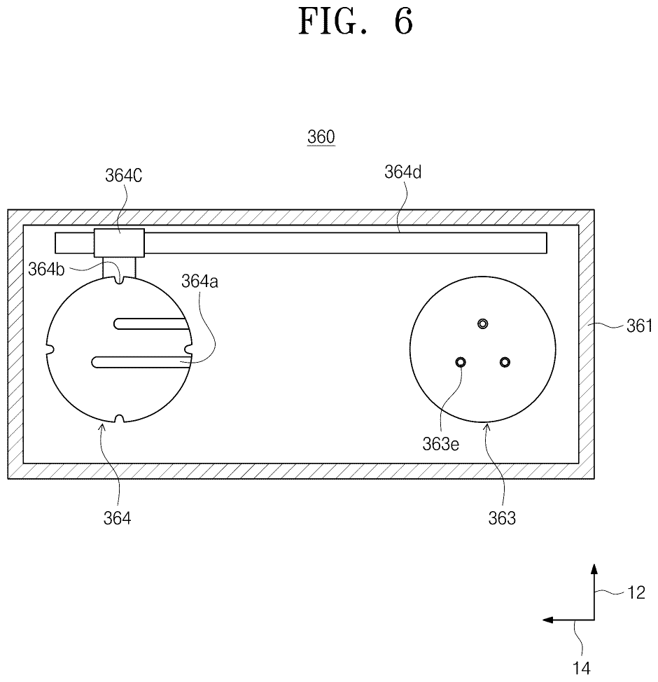

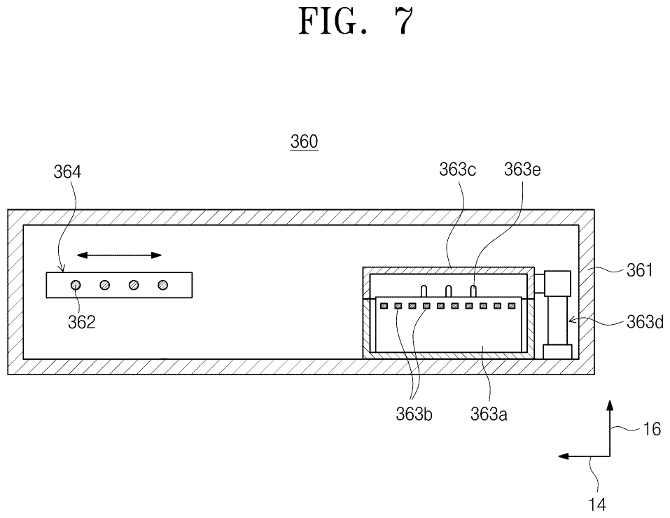

FIG. 6 is a top plan view schematically illustrating an example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in the shape of a generally rectangular parallelepiped. In the lateral wall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 361.

The heating unit 363 includes a heating plate 363a, a lift pin 363e, and a cover 363c.

The heating plate 363a has a substantially circular shape when viewed above. The heating plate 363a may have a larger diameter than the substrate W.

The heating plate 363a supports the liquid-treated substrate W. In this case, the liquid-treated substrate W may be transferred from the transfer plate 364. The heating plate 363a may be provided with a plurality of holes with which the lift pins 363e communicate. The heating plate 363a is heated when is supplied with power. The heated heating plate 363a may heat the liquid-treated substrate W to soft-bake or hard-bake the liquid. The heating plate 363a may include a base layer 363a1, an insulating layer 363a5, a heating wire layer 363a2, a protective layer 363a3, and a metal bond when viewed from a cross section with a longitudinal incision, and will be described in more detail later.

The lift pin 363e is provided to communicate with heating plate 363a. The lift pin 363e is provided to be movable in an up and down direction along the third direction 16. The lift pin 363e receives the substrate W from the transfer robot 351 and places the received substrate W down on the heating plate 363a, or lifts the substrate W from the heating plate 363a and hands the substrate W to the transfer robot 351. According to the example, three lift pins 363e may be provided.

The cover 363c has a space with an open lower portion therein. The cover 363c is located above the heating plate 363a and is moved in a vertical direction by a driver 363d. The space formed by the cover 363c and the heating plate 363a according to the movement of the cover 363c is provided as a heating space for heating the substrate W.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands 352 of the transfer robot 351 described above. Further, the notches 364b are provided in a number corresponding to the protrusions 352b formed on the hand 352, and are formed at locations corresponding to the protrusions 352b. When the upper and lower positions of the hand 352 and the transfer plate 364 are changed from the position where the hand 352 and the transfer plate 364 are aligned in the vertical direction, the substrate W is transferred between the hand 352 and the transfer plate 364. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and lift pins 363e from interfering with each other when the substrate W is transferred between the transfer plate 364 and the heating unit 363.

The transfer plate 364 is provided with a thermally conductive material. In one example, the transfer plate 364 may be provided from a metal material.

Within the transfer plate 364, a cooling flow path 364a is formed. The cooling flow path 364a is supplied with cooling water. The substrate W, which has been completely heated in the heating unit 363, may be cooled while being transferred by the transfer plate 364. Also, the substrate W may be cooled on the transfer plate 364 while the transfer plate 364 is stopped for the substrate W to be taken over by the transfer robot 351.

Optionally, a cooling unit may be further provided within the housing 361. In this case, the cooling unit may be arranged in parallel with the heating unit 363. The cooling unit may be provided as a cooling plate having a passage formed therein through which coolant flows. The substrate that has been heated in the heating unit may be returned to the cooling unit for cooling.

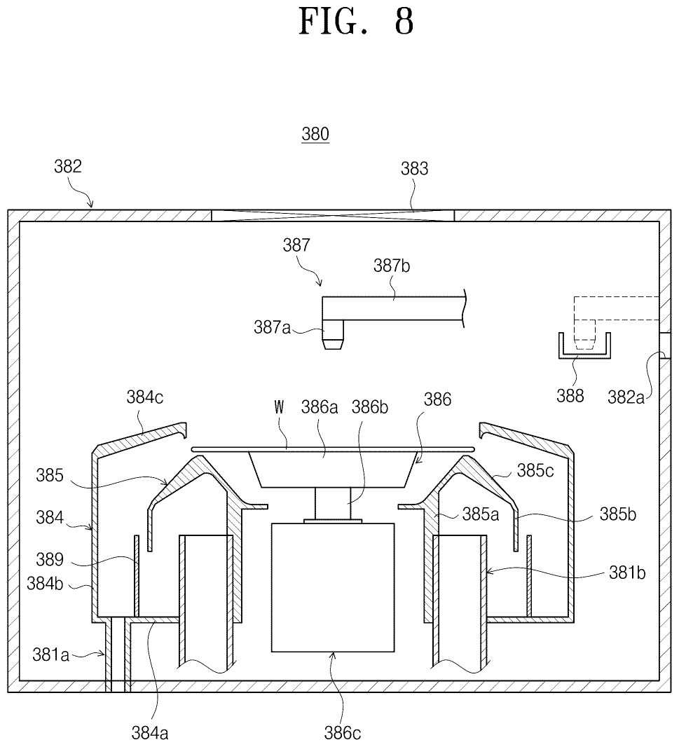

FIG. 8 is a front view schematically illustrating the liquid treating chamber of FIG. 3 or 4.

Referring to FIG. 8, the liquid treating chamber 380 includes a housing 382, an outer cup 384, a support unit 386, and a liquid supply unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An inner space of the housing 382 is provided with the outer cup 384. The outer cup 384 has a treatment space with an open top.

The support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment solution onto the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid. The liquid supply unit 387 has a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position. In the process position, the nozzle 387a supplies the treatment solution to the substrate W placed on the support plate 386a, and after completing the supply of the treatment solution, the nozzle 387a waits in the standby position. In the standby position, the nozzle 387a waits at a groove port 388, the groove port 388 is located on the outside of the outer cup 384 within the housing 382.

On the top wall of the housing 382, a fan filter unit 383 is disposed to supply a downward airflow to the inner space. The fan filter unit 383 includes a fan that introduces air from the outside into the inner space and a filter that filters the air from the outside.

The outer cup 384 includes a bottom wall 384a, a lateral wall 384b, and a top wall 384c. The inner portion of the outer cup 384 is provided as the inner space described above. The inner space H includes a treatment space at the top and an exhaust space at the bottom.

The bottom wall 384a is provided in a circular shape and has an opening in the center. The lateral wall 384b extends upwardly from the outer end of the bottom wall 384a. The lateral wall 384b is provided in a ring shape and is provided vertical to the bottom wall 384a. In one example, the lateral wall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the lateral wall 384b toward the center axis of the outer cup 384.

The guide cup 385 is located on the inner side of the outer cup 384. The guide cup 385 has an inner wall 385a, an outer wall 385b, and a top wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the lateral wall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. The gas-liquid separation plate 389 may be provided to extend upwardly from the bottom wall 384a of the outer cup 384. The gas-liquid separation plate 1230 may be provided in a ring shape. The gas-liquid separation plate 389 may be located between the lateral wall 384b of the outer cup 384 and the outer wall 385b of the guide cup 385 when viewed from above. The top end of the gas-liquid separation plate 389 may be located lower than the bottom end of the outer wall 385b of the guide cup 385.

The bottom wall 384a of the outer cup 384 is connected to an outlet pipe 381a for discharging the treatment liquid and an exhaust pipe 381b. The outlet pipe 381a may be connected to the outer cup 384 from the outer side of the gas-liquid separation plate 389. The exhaust pipe 381b may be connected to the outer cup 384 from an inner side of the gas-liquid separation plate 389.

The interface module 500 connects the treating module 300 with an external exposure device 700. The interface module 500 includes an interface frame 501, a buffer unit 510, a cooling unit 520, a transfer mechanism 530, an interface unit 540, and an additional process chamber 560.

The top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 has a hand 542 on which the substrate W is placed, and the hand 542 may be provided to be movable forwardly and backwardly, rotatable about an axis parallel to the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

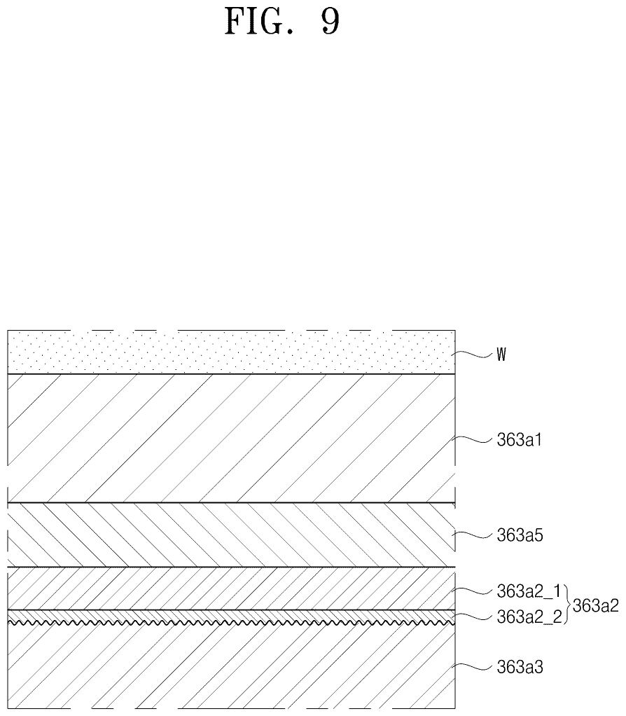

FIG. 9 is a partial cross-sectional view of a heating plate illustrated in FIG. 7 through a longitudinal incision.

As illustrated in FIG. 9, the heating plate 363a includes a base layer 363a1, a heating wire layer 363a2, and a protective layer 363a3, and may further include an insulating layer 363a5.

The substrate W is disposed on the base layer 363a1. In this case, the base layer 363a1 may be further formed with support pins (not illustrated), and the substrate W may be supported by the support pins (not illustrated). When the substrate W is supported on the support pins (not illustrated), the substrate W may be spaced apart from the top surface of the base layer 363a1. The base layer 363a1 is formed of a thermally conductive material to emit heat conducted from the heating wire layer 363a2 described later to the substrate W side. The base layer 363a1 may be formed of a ceramic material or a non-conductive material. For example, the base layer 363a1 may be formed of any one of aluminum nitride, silica, and silicon nitride. Additionally, the base layer 363a1 may be schematically formed as a disk shape when viewed from top to bottom. In this case, the thickness of the base layer 363a1 may optionally be formed within a range of 1.5 mm to 5 mm.

The heating wire layer 363a2 may be positioned on a lower portion of the base layer 363a1. The heating wire layer 363a2 may be formed in a loop-shaped pattern that has a regular path and forms a bend when viewed from top to bottom with reference to FIG. 9. Furthermore, the heating wire layers 363a2 formed in the loop-shaped pattern may be provided in plural while being spaced apart from each other. In this case, the plurality of heating wire layers 363a2 may be arranged spaced apart with respect to the center of the base layer 363a1 so as to cover the entire area of the base layer 363a1 formed in the shape of a disc. Further, the heating wire layer 363a2 may be formed on the insulating layer 363a5 in the case where the insulating layer 363a5 is formed, and may be formed on the base layer 363a1 in the case where the insulating layer 363a5 is not formed. The heating wire layer 363a2 is formed including a metallic material and may be heated when is supplied with power. The heated heating wire layer 363a2 conducts heat to the base layer 363a1 to heat the substrate W.

In one example, the heating wire layer 363a2 may include an upper layer 363a2_1 and a lower layer 363a2_2.

The upper layer 363a2_1 may be formed on top of the lower layer 363a2_2. In this case, the upper layer 363a2_1 may be formed including a transition metal material. For example, the upper layer 363a2_1 may include a precious metal and a platinum group metal or an alloy of the precious metal and the platinum group metal. In this case, as an example of the precious metal, the precious metal may be formed of copper (Cu), silver (Ag), or gold (Au). Further, as an example of the platinum group metals, the platinum group metals may be formed of platinum (Pt) or palladium (Pd). As such, the heating wire layer 363a2 including the transition metal material may be heated when is supplied with power and conduct heat to the base layer 363a1. In this case, the thickness of the heating wire layer 363a2 may optionally be formed within a range of 0.01 mm to 0.1 mm.

Further, the upper layer 363a2_1 may further include a ceramic material. For example, the upper layer 363a2_1 may be formed of a silicon dioxide material. Thus, the upper layer 363a2_1 prevents carbonization of the transition metal material even at a high temperature by the ceramic material while the transition metal material is heated. Furthermore, the upper layer 363a2_1 is able to maintain high thermal conductivity by the ceramic material.

Furthermore, the upper layer 363a2_1 may further include a heat dissipating material. As one example of the heat dissipating material, the heat dissipating material may be aluminum oxide. Accordingly, the heating wire layer 363a2 may have increased thermal conductivity, which may facilitate heat conduction to the base layer 363a1 upon heating.

On the other hand, the lower layer 363a2_2 may include a metal bond. The metal bond is located between the top layer 363a2_1 and the protective layer 363a3, and serves to facilitate increasing the resistance of the heating wire layer 363a2. As one example of forming the metal bond, the metal bond may be formed by bonding the transition metal material of the upper layer 363a2_1 with the additive material of the protective layer 363a3 described later. In one example, when the upper layer 363a2_1 is formed of AgPd that is the transition metal material and silicon dioxide (SiO₂) that is the ceramic material, and the protective layer 363a3 is formed of silicon dioxide (SiO₂) that is the ceramic material and PbO that is the additive material PbO, the additive material PbO may be mixed near the bonding surface of the transition metal material AgPd to form the metal bond, the lower layer 363a2_2. Thus, when the additive material contained in the protective layer is mixed with the transition metal material of the upper layer 363a2_1 to form the metal bond of the lower layer 363a2_2, the resistance of the heating wire layer 363a2 may be easily increased. Here, the thickness of the metal bond of the lower layer 363a2_2 may optionally be formed within a range of 0.001 mm to 0.02 mm. Furthermore, the thickness of the metal bond of the lower layer 363a2_2 may be formed unevenly according to the heating method of the heating wire layer 363a2 described hereinafter.

The protective layer 363a3 is located on the lower portion of the heating wire layer 363a2, and may include a ceramic material and an additive material. For example, the protective layer 363a3 may include silicon dioxide (SiO₂) as the ceramic material and may include any one of PbO, V₂O₂, and TeO₂ as the additive material. The protective layer 363a3 may protect the heating wire layer 363a2 by preventing the heating wire layer 363a2 from being exposed to the outside, thereby preventing oxidation of the heating wire layer 363a2 and preventing power from the heating wire layer 363a2 from leaking to the outside. The thickness of the protective layer 363a3 may optionally be formed within a range of 0.01 mm to 0.2 mm.

Further, the protective layer 363a3 may further include a heat dissipating material. As one example of the heat dissipating material, the heat dissipating material may be aluminum oxide. Accordingly, the protective layer 363a3 may have an increased thermal conductivity, which may increase the cooling rate of the heating wire layer 363a2 upon cooling of the heating wire layer 363a2, thereby shortening the cooling time.

The insulating layer 363a5 may be formed between the base layer 363a1 and the heating wire layer 363a2. The insulating layer 363a5 may be omitted when the base layer 363a1 is a non-conductor, and may be formed to insulate between the base layer 363a1 and the heating wire layer 363a2 when the base layer 363a1 is a conductor.

Hereinafter, a method of manufacturing a heating plate according to an exemplary embodiment of the present invention will be described.

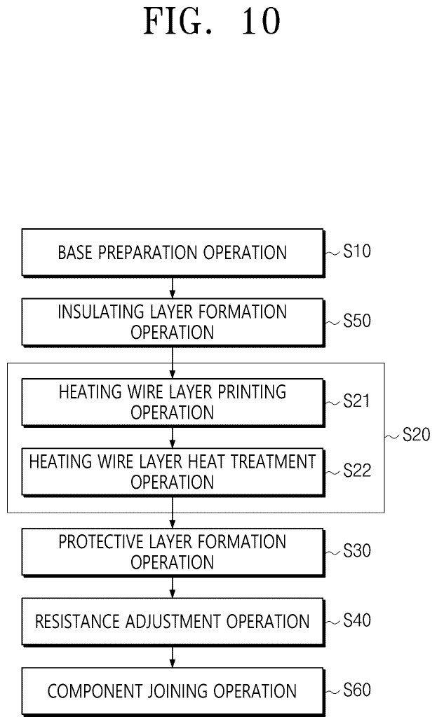

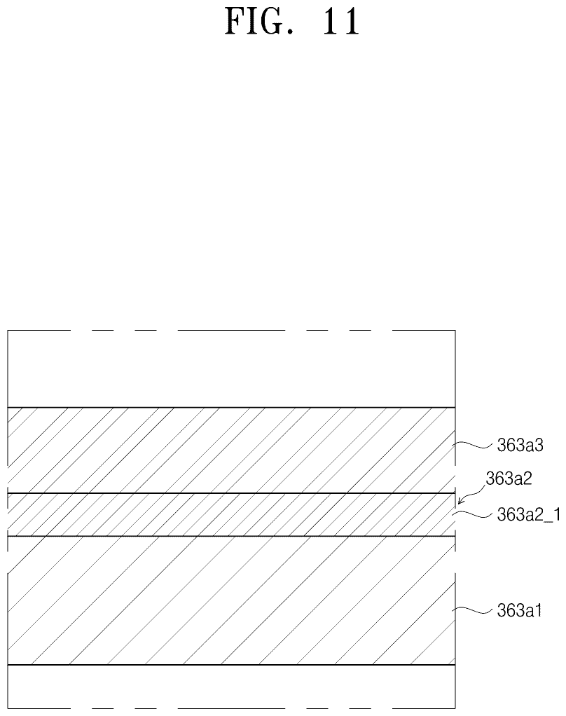

FIG. 10 is a flowchart of a method of manufacturing a heating plate according to an exemplary embodiment of the present invention. FIGS. 11 to 13 are partial cross-sectional views of the heating plate according to the sequence of the method of manufacturing the heating plate illustrated in FIG. 10. FIGS. 11 to 13 illustrate the heating plate illustrated in FIG. 9 in an inverted state.

As illustrated in FIG. 10, a method of manufacturing a heating plate according to an exemplary embodiment of the present invention includes a base preparation operation S10, a heating wire layer formation operation S20, a protective layer formation operation S30, and a resistance adjustment operation S40, and may further include an insulating layer formation operation S50 and a component joining operation S60.

First, the base preparation operation S10 is an operation to prepare a base layer 363a1, as illustrated in FIG. 11. The base layer 363a1 may be schematically formed in the shape of a disk when viewed from top to bottom, as described above. Further, the base layer 363a1 may be formed of a ceramic material or a metal material having high thermal conductivity, as described above.

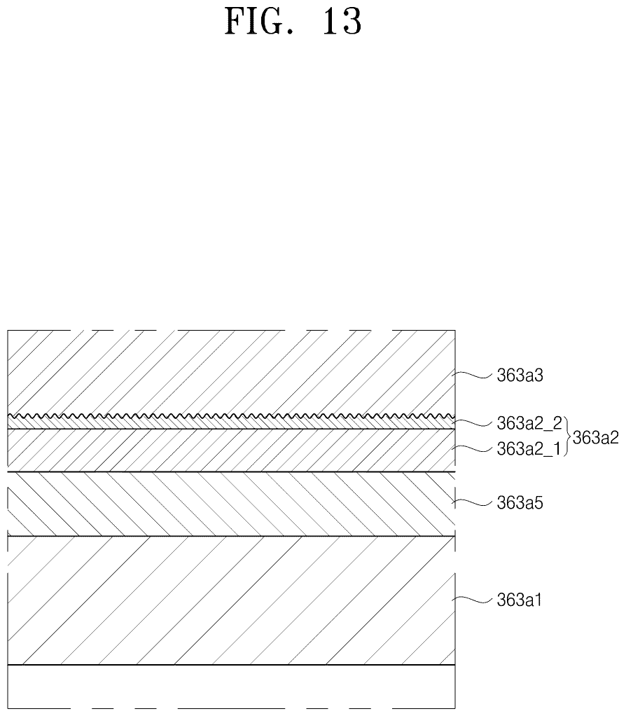

In the heating wire layer formation operation S20, the heating wire layer 363a2 is formed on the basis of the base layer 363a1, as illustrated in FIG. 11. The heating wire layer formation operation S20 may form the heating wire layer 363a2 on the insulating layer 363a5 in the presence of the insulating layer 363a5, as illustrated in FIG. 13. In this case, the heating wire layer 363a2 may be provided in the form of a loop-shaped pattern when viewed from top to bottom as described above, and may be formed in a plurality. Furthermore, the heating wire layer 363a2 formed by the heating wire layer formation operation S20 may be formed of the same material as the material of the upper layer 363a2_1 described above. Accordingly, the heating wire layer 363a2 formed by the heating wire layer formation operation S20 may include a transition metal material as exemplified above, and may further include a ceramic material and a heat dissipating material.

As one example of the heating wire layer formation operation S20, the heating wire layer formation operation S20 may include a heating wire layer printing operation S21 and a heating wire layer heat treatment operation S22.

In the heating wire layer printing operation S21, the heating wire layer 363a2 is printed in the form of a pattern based on the base layer 363a1.

The heating wire layer heat treatment operation S22 may heat treat the printed heating wire layer 363a2. In this case, the heating wire layer 363a2 may be sintered by heating the heating wire layer 363a2 printed in the heating wire layer printing operation S21 and then cooling the heating wire layer 363a2.

In this way, the heating wire layer 363a2 formed by the heating wire layer printing operation S21 and the heating wire layer heat treatment operation S22 may be fabricated in the form of a pattern with a very thin thickness as described above. For example, the heating wire layer 363a2 may be formed with a thickness within a range of 0.01 mm to 0.1 mm.

In the protective layer formation operation S30, a protective layer 363a3 is formed based on the heating wire layer 363a2, as illustrated in FIG. 11. The protective layer 363a3 may be located at a lower portion of the heating wire layer 363a2, as described above, and may be formed of a second material. Further, the protective layer 363a3 may be formed including a ceramic material and an additive material, as described above, to protect the heating wire layer 363a2 by preventing the heating wire layer 363a2 from being exposed to the outside. As one example of the second material, the second material may include silicon dioxide as the ceramic material and may include any one of PbO, V₂O₂, and TeO₂ as the additive material. In addition, the protective layer 363a3 may further include a heat dissipating material that increases thermal conductivity to increase the heat treatment efficiency of the substrate W as described above. In this case, the protective layer formation operation S30 may be formed by printing the protective layer 363a3 on the heating wire layer 363a2.

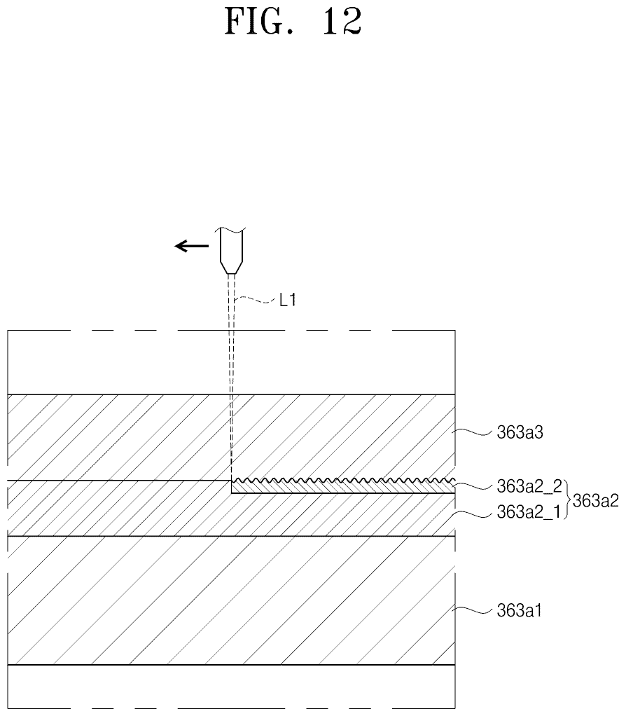

The resistance adjustment operation S40 is an operation to adjust the resistance of the heating wire layer 363a2. Specifically, in the resistance adjustment operation S40, the resistance of the heating wire layer 363a2 is adjusted by heating the heating wire layer 363a2 to a temperature or above at which the additive material of the protective layer 363a3 melts, causing the heated heating wire layer 363a2 to melt the additive material, and causing the melted additive material to be bonded with the transition metal material of the heating wire layer 363a2 to form a metal bond. In this case, the metal bond corresponds to the lower layer 363a2_2 of the heating wire layer 363a2 as described above. Here, the method of melting the additive material in the resistance adjustment operation S40 may be to melt the additive material by irradiating the protective layer 363a3 and the heating wire layer 363a2 with a laser L1 as illustrated in FIG. 12. In this case, as the laser L1, a UV laser or an IR laser may be used. In this case, the laser may be irradiated at any one wavelength selected within 300 nm to 500 nm. The laser L1 may penetrate the protective layer 363a3 and be emitted to the heating wire layer 363a2. In this case, the laser L1 may be emitted by traveling in a direction that is horizontal to one wide surface of the protective layer 363a3. In this case, since the protective layer 363a3 is formed of a ceramic material through which the laser L1 may be penetrated, the laser L1 may be emitted to the heating wire layer 363a2 in the state of having penetrating the protective layer 363a3. Then, the laser L1 emitted on the heating wire layer 363a2 heats the transition metal material of the protective layer 363a3 and the heating wire layer 363a2. At this time, since the additive material has a melting point lower than the melting point of the transition metal material of the heating wire layer 363a2, the additive material is melted by the transition metal material of the heated heating wire layer 363a2. Then, between the upper layer 363a2_1 of the heating wire layer 363a2 and the protective layer 363a3, the transition metal material and the additive material are bonded by melting to form the lower layer 363a2_2, which is a metal bond. In this case, the lower layer 363a2_2, which is the metal bond, interferes with the electrical path of the heating wire layer 363a2, thereby increasing the resistance of the heating wire layer 363a2. In addition, the lower layer 363a2_2, which is the metal bond, is oxidized by melting, thereby increasing the resistance of the heating wire layer 363a2. For example, the lower layer 363a2_2, which is the metal bond, may increase the resistance of the heating wire layer 363a2 because AgPd is oxidized to produce an oxide material, such as AgPd—O. In this way, the resistance of the heating wire layer 363a2 may increase depending on the amount of production and the amount of oxidation of the lower layer 363a2_2, which is the metal bond.

Thus, the method of manufacturing the heating plate according to the exemplary embodiment of the present invention may easily adjust the resistance value of the heating wire layer 363a2 to a required value by generating the lower layer 363a2_2, which is the metal bond.

At this time, in the resistance adjustment operation S40, the resistance of the heating wire layer 363a2 may be adjusted by increasing the amount of the additive material melted to the transition metal material contained in the upper layer 363a2_1. For example, by increasing the content of the additive material or increasing the irradiation intensity of the laser so that a larger amount of the additive material is melted into the transition metal material than in the example described above, the resistance of the heating wire layer 363a2 may be easily adjusted.

On the other hand, the insulating layer formation operation S50 may be performed between the base preparation operation S10 and the heating wire layer formation operation S20, and may be performed when the base layer 363a1 is a conductor including an electrically conductive material. The insulating layer formation operation S50 forms an insulating layer 363a5 between the base layer 363a1 and the heating wire layer 363a2, as illustrated in FIG. 13. The insulating layer 363a5 insulates between the base layer 363a1 and the heating wire layer 363a2 to prevent current leakage from the heating wire layer 363a2 to the base layer 363a1. On the other hand, when the base layer 363a1 is formed of a non-conductor, the heating wire layer 363a2 may be formed on the base layer 363a1 as described above.

In the component joining operation S60, a terminal (not illustrated) may be electrically connected to each of the opposite ends of the heating wire layer 363a2 whose resistance has been adjusted by the resistance adjustment operation S40, or a temperature sensor (not illustrated) for measuring the temperature of the heating wire layer 363a2 may be joined to the protective layer 363a3.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A heating plate for supporting and heating a substrate, the heating plate comprising:
a base layer on which a substrate is seated;
a heating wire layer located under the base layer and including a transition metal material and a metal bond; and
a protective layer located under the heating wire layer and including a ceramic material and an additive material,
wherein the additive material is melted at a lower temperature than the ceramic material and the transition metal material, and
the metal bond is a material produced by bonding of components contained in the transition metal material and the additive material.

2. The heating plate of claim 1, wherein the heating wire layer includes:
an upper layer including the transition metal material; and
a lower layer including the transition metal material and the metal bond, and
the upper layer is not provided with the metal bond.

3. The heating plate of claim 1, wherein the additive material has a melting point lower than a melting point of the transition metal material.

4. The heating plate of claim 1, wherein the heating wire layer includes a precious metal, a platinum group metal, or an alloy of the precious metal and the platinum group metal.

5. The heating plate of claim 1, wherein the heating wire layer further includes a ceramic material and a heat dissipating material.

6. The heating plate of claim 5, wherein the heat dissipating material is aluminum oxide.

7. The heating plate of claim 1, wherein the protective layer includes silicon dioxide as the ceramic material and includes any one of PbO, V₂O₂, and TeO₂ as the additive material.

8. The heating plate of claim 1, wherein the protective layer further includes a heat dissipating material.

9. The heating plate of claim 8, wherein the heat dissipating material is aluminum oxide.

10. The heating plate of claim 1, wherein the heating wire layer is supplied with power to be heated, and
the heat generated in the heating wire layer is conducted through the base layer to the substrate.

11-20. (canceled)
